(19) United States
(12) Patent Application Publication
(10) Pub. No.: US 2026/0066772 A1
(43) Pub. Date: Mar. 5, 2026

(54) POWER SEMICONDUCTOR DRIVE DEVICE

(71) Applicant: Mitsubishi Electric Corporation, Tokyo (JP)

(72) Inventors: Motoki IMANISHI, Tokyo (JP); Mitsutaka HANO, Tokyo (JP)

(73) Assignee: Mitsubishi Electric Corporation, Tokyo (JP)

(21) Appl. No.: 19/173,789

(22) Filed: Apr. 8, 2025

(30) Foreign Application Priority Data
Aug. 28, 2024 (JP) 2024-146251

(51) Int. Cl. H02M 1/092; H03K 17/567; H03K 17/60; H03K 17/74

(52) U.S. Cl. CPC H02M 1/092; H03K 17/567; H03K 17/602; H03K 17/74

(57) ABSTRACT

An object is to provide a technique capable of appropriately driving a plurality of power semiconductor elements each having reference potential different from each other. A power semiconductor drive device includes: a conversion circuit converting a serial signal from an outer part into a plurality of parallel signals; a plurality of drive circuits driving a plurality of power semiconductor elements each having reference potential different from each other, respectively; a plurality of level shift circuits connected between the conversion circuit and the plurality of drive circuits and level-shifting the plurality of parallel signals in accordance with the reference potential of the plurality of power semiconductor elements, respectively; and a voltage holding structure electrically separating each of the plurality of drive circuits.

### BACKGROUND

### Technical Field

The present disclosure relates to a power semiconductor drive device.

### Description of the Background Art

Various techniques are proposed for a power semiconductor drive device. For example, Japanese Patent Application Laid-Open No. 2016-171438 proposes a technique of driving a plurality of switches using a plurality of parallel signals converted from a serial signal.

### SUMMARY

In the meanwhile, required recently is driving of a plurality of power semiconductor elements each having reference potential different from each other. However, there is a problem that a configuration of Japanese Patent Application Laid-Open No. 2016-171438 itself cannot appropriately drives the plurality of power semiconductor elements each having reference potential different from each other.

The present disclosure therefore has been made to solve the above problems, and it is an object to provide a technique capable of appropriately driving a plurality of power semiconductor elements each having reference potential different from each other.

A power semiconductor drive device according to the present disclosure includes: a conversion circuit converting a serial signal from an outer part into a plurality of parallel signals; a plurality of drive circuits driving a plurality of power semiconductor elements each having reference potential different from each other, respectively; a plurality of level shift circuits connected between the conversion circuit and the plurality of drive circuits and level-shifting the plurality of parallel signals in accordance with the reference potential of the plurality of power semiconductor elements, respectively; and a voltage holding structure electrically separating each of the plurality of drive circuits.

The plurality of power semiconductor elements each having reference potential different from each other can be appropriately driven.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a circuit diagram illustrating a configuration of a power semiconductor drive device according to an embodiment 1.

FIG. 2 is a circuit diagram illustrating a configuration of the power semiconductor drive device according to the embodiment 1.

FIG. 3 is a circuit diagram illustrating a configuration of a related device.

FIG. 4 is a circuit diagram illustrating a configuration of a related device.

FIG. 5 is a circuit diagram illustrating a configuration of a power semiconductor drive device according to an embodiment 2.

FIG. 6 is a circuit diagram illustrating a configuration of the power semiconductor drive device according to the embodiment 2.

### DESCRIPTION OF THE PREFERRED EMBODIMENTS

Embodiments are described with reference to the appended diagrams hereinafter. Features described in each embodiment described below is exemplification, thus all features are not necessarily applied. The same or similar reference numerals will be assigned to similar constituent elements in a plurality of embodiments in the description hereinafter, and the different constituent elements are mainly described hereinafter.

### EMBODIMENT 1

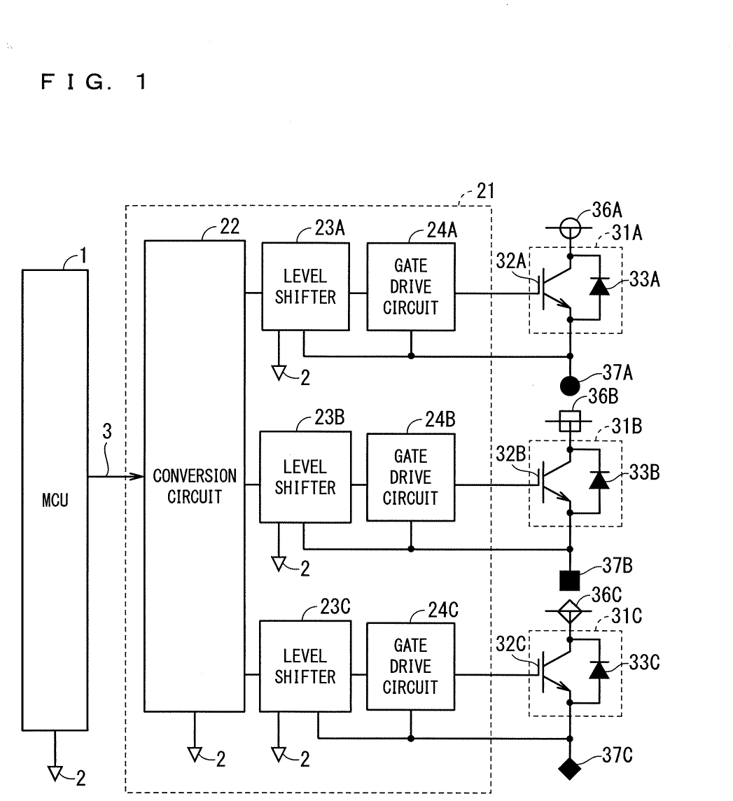

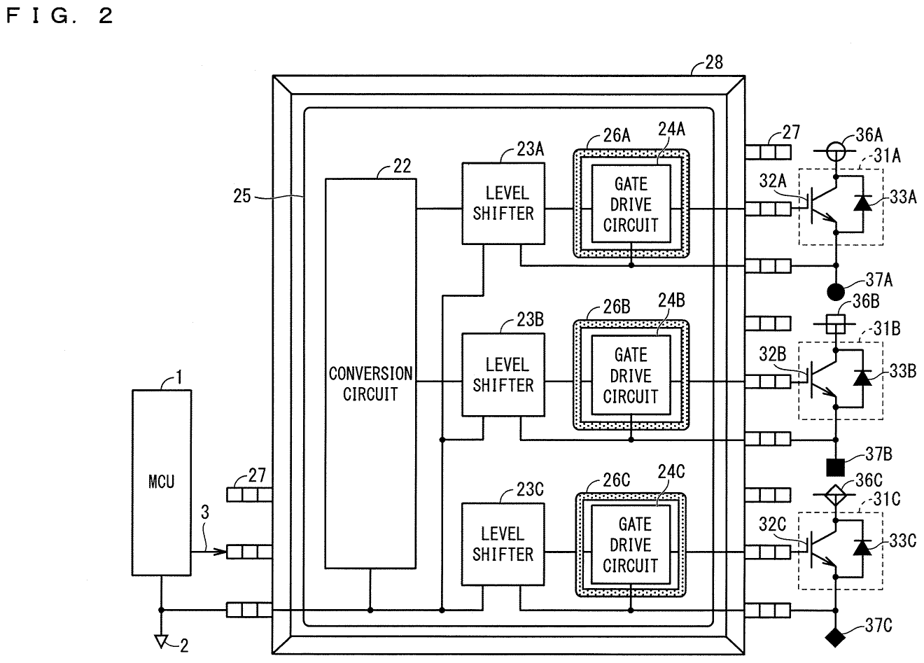

FIG. 1 is a circuit diagram illustrating a configuration of a power semiconductor drive device 21 according to the present embodiment 1, and FIG. 2 is a circuit diagram in which a diagram of a chip configuration of the power semiconductor drive device 21 is added to the configuration in FIG. 1. The power semiconductor drive device 21 is connected between a micro controller unit (MCU) 1 and a plurality of power semiconductor elements 31A to 31C. The MCU 1 and the plurality of power semiconductor elements 31A to 31C are described before the description of the power semiconductor drive device 21.

The MCU 1 transmits a serial signal 3 with reference potential 2 of the MCU 1 as a reference to the power semiconductor drive device 21.

The power semiconductor element 31A includes an IGBT 32A and a reflux diode 33A. A collector of the IGBT 32A is connected to high potential 36A and a cathode of the reflux diode 33A. A gate of the IGBT 32A is connected to the power semiconductor drive device 21. An emitter of the IGBT 32A is connected to low potential 37A as reference potential and an anode of the reflux diode 33A. The reflux diode 33A may be a Schottky barrier diode (SBD) or a PN junction diode (PND).

A power semiconductor element 31B includes an IGBT 32B and a reflux diode 33B, and is connected between high potential 36B and lower potential 37B in the manner similar to the power semiconductor element 31A. A power semiconductor element 31C includes an IGBT 32C and a reflux diode 33C, and is connected between high potential 36C and lower potential 37C in the manner similar to the power semiconductor element 31A. Each of the high potential 36A, 36B, and 36C is different from each other, and each of the low potential 37A to 37C is also different from each other.

The number of the power semiconductor elements is three in FIG. 1 and FIG. 2, but is not limited thereto. Two power semiconductor elements or four or more power semiconductor elements are also applicable. Although the power semiconductor element in FIG. 1 and FIG. 2 includes the IGBT, the configuration is not limited thereto. The power semiconductor element may include a metal oxide semiconductor field effect transistor (MOSFET) or a reverse conducting-IGBT (RC-IGBT).

The power semiconductor drive device 21 is described next. The power semiconductor drive device 21 includes a conversion circuit 22, a plurality of level shifters 23A to 23C as a plurality of level shift circuits, and a plurality of gate drive circuits 24A to 24C as a plurality of drive circuits. As illustrated in FIG. 2, the power semiconductor drive device 21 includes a plurality of voltage holding structures 26A to 26C, an electrode terminal 27, and a package 28.

Upon receiving the serial signal 3 from the MCU 1 as an outer part via the electrode terminal 27, the conversion circuit 22 converts the serial signal 3 into a plurality of parallel signals with the reference potential 2 as a reference. The plurality of parallel signals are parallel signals whose number is the same as that of the plurality of power semiconductor elements, and is three parallel signals in the examples in FIG. 1 and FIG. 2.

The plurality of level shifters 23A to 23C are connected between the conversion circuit 22 and the plurality of gate drive circuits 24A to 24C. The plurality of level shifters 23A to 23C level-shift the plurality of parallel signals generated in the conversion circuit 22 in accordance with the reference potential of the plurality of power semiconductor elements 31A to 31C, respectively. In the present embodiment 1, the reference potential of the plurality of power semiconductor elements 31A to 31C is the low potential 37A to 37C, but may be the high potential 36A to 36C.

The plurality of gate drive circuits 24A to 24C control gate voltage of the plurality of power semiconductor elements 31A to 31C based on the plurality of parallel signals level-shifted in the plurality of level shifters 23A to 23C, respectively. Accordingly, the plurality of gate drive circuits 24A to 24C drive the plurality of power semiconductor elements 31A to 31C, respectively.

The plurality of voltage holding structures 26A to 26C in FIG. 2 electrically separate the plurality of gate drive circuits 24A to 24C, respectively. In the present embodiment 1, the conversion circuit 22, the plurality of level shifters 23A to 23C, the plurality of gate drive circuits 24A to 24C, and the plurality of voltage holding structures 26A to 26C are provided on one semiconductor substrate 25, and the semiconductor substrate 25 is made of normal silicon (Si). The semiconductor substrate 25 may be made of wide bandgap semiconductor such as silicon carbide (SiC), gallium nitride (GaN), gallium oxide (Ga₂O₃), or diamond. When the semiconductor substrate 25 is made of wide bandgap semiconductor, stable operation at a high temperature and high voltage and increased switching speed can be achieved.

The plurality of voltage holding structures 26A to 26C may have a high voltage RESURF structure using pn junction or a silicon on insulator (SOI) structure using dielectric isolation. In the example in FIG. 1 and FIG. 2, the voltage holding structure is the plurality of voltage holding structures 26A to 26C, but may be one voltage holding structure in which the plurality of voltage holding structures 26A to 26C are integrated.

The package 28 is made of insulative resin, and covers the semiconductor substrate 25. The electrode terminal 27 partially and electrically connects an inner part and an outer part of the package 28.

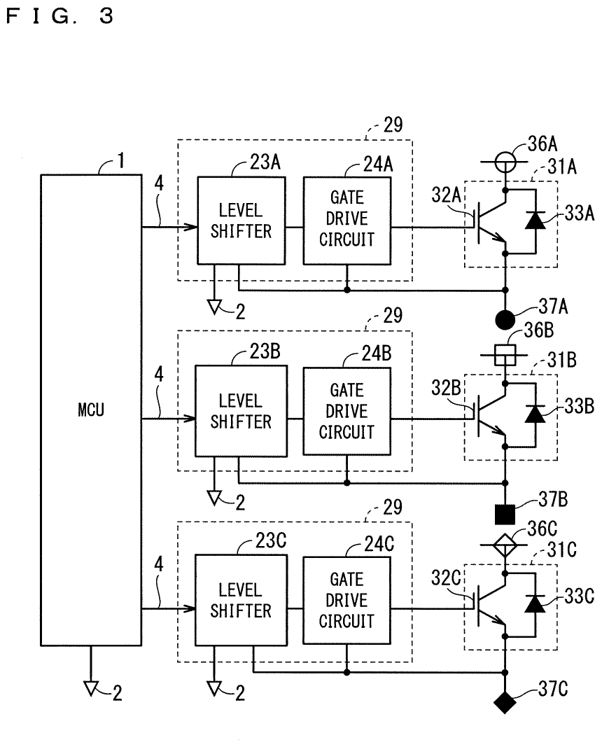

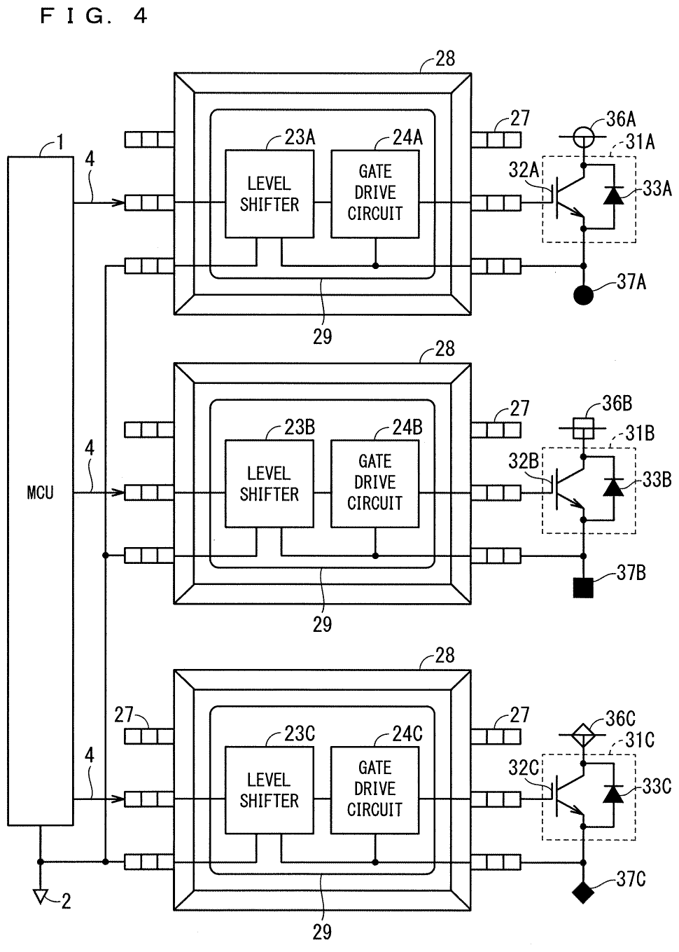

FIG. 3 is a circuit diagram illustrating a configuration of a related device of the power semiconductor drive device 21 according to the present embodiment 1, and FIG. 4 is a circuit diagram in which a diagram of a chip configuration of the related device is added to the configuration in FIG. 3.

In the related device, the MCU 1 does not transmit the serial signal but transmits the plurality of parallel signals 4. Thus, signal processing and a signal wiring in the MCU 1 are complicated. In contrast, in the present embodiment 1, the power semiconductor drive device 21 includes the conversion circuit 22 converting the serial signal into the plurality of parallel signals. Thus, the signal processing and the signal wiring in the MCU 1 can be simplified.

The related device includes the plurality of level shifters 23A to 23C level-shifting the plurality of parallel signals 4 transmitted from the MCU 1 in accordance with the low potential 37A to 37C as the reference potential of the plurality of power semiconductor elements 31A to 31C. Thus, the related device can drive the plurality of power semiconductor elements 31A to 31C each having reference potential different from each other. However, there is a problem that a size and cost of the device increases by reason that a plurality of semiconductor chips 29 (the plurality of packages 28) are provided in accordance with the low potential 37A to 37C as the reference potential of the plurality of power semiconductor element 31A to 31C.

In contrast, according to the power semiconductor drive device 21 according to the present embodiment 1, the plurality of voltage holding structures 26A to 26C electrically separate the plurality of gate drive circuits 24A to 24C, respectively. Accordingly, the conversion circuit 22, the plurality of level shifters 23A to 23C, the plurality of gate drive circuits 24A to 24C, and the plurality of voltage holding structures 26A to 26C can be provided on one semiconductor substrate 25. Thus, the size and cost of the power semiconductor drive device 21 can be suppressed.

When the plurality of voltage holding structures 26A to 26C include the high voltage RESURF structure using pn junction, a resistance value of the pn junction can be easily changed. Thus, withstand voltage can be easily controlled. When the plurality of voltage holding structures 26A to 26C include a structure using dielectric isolation (an SOI structure, for example), a parasitic operation can be suppressed, and the power semiconductor drive device having high robustness can be achieved.

### EMBODIMENT 2

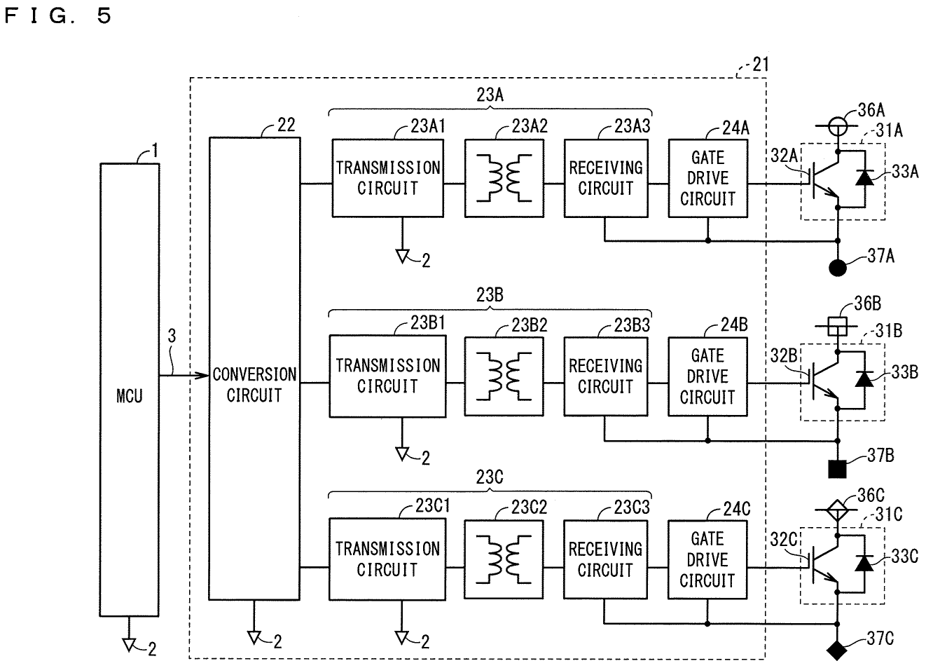

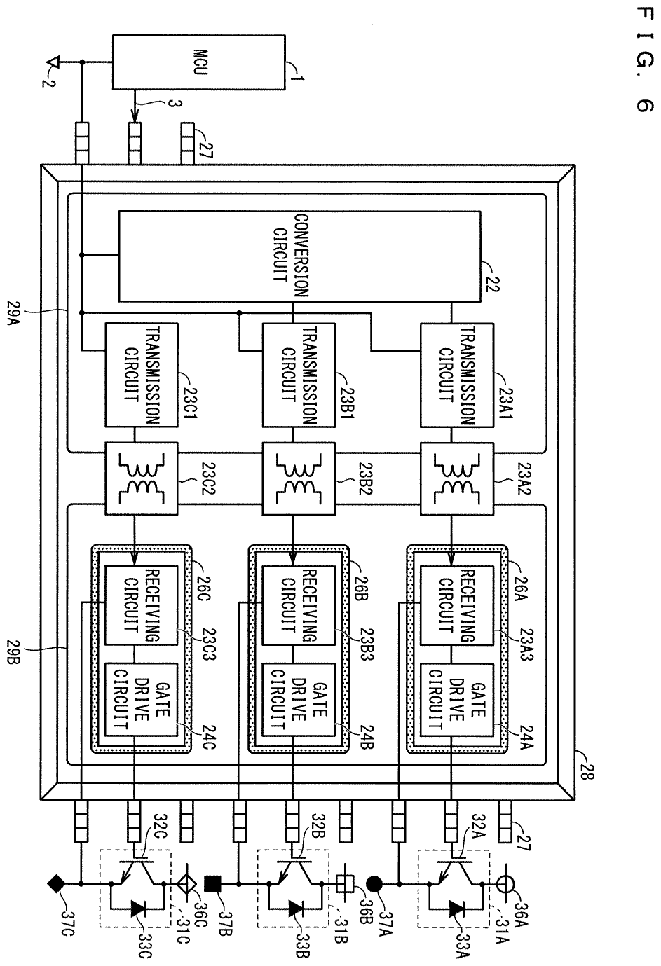

FIG. 5 is a circuit diagram illustrating a configuration of the power semiconductor drive device 21 according to the present embodiment 2, and FIG. 6 is a circuit diagram in which a diagram of a chip configuration of the power semiconductor drive device 21 is added to the configuration in FIG. 5.

In the present embodiment 2, the conversion circuit 22 is provided to a first semiconductor chip 29A, and the plurality of gate drive circuits 24A to 24C and the plurality of voltage holding structure 26A to 26C are provided to a second semiconductor chip 29B as illustrated in FIG. 6. The first semiconductor chip 29A and the second semiconductor chip 29B are insulated by a space or an insulator.

In the present embodiment 2, each of the plurality of level shifters 23A to 23C includes a coupled circuit transmitting a signal from the first semiconductor chip 29A to the second semiconductor chip 29B while keeping insulation between the first semiconductor chip and the second semiconductor chip. As illustrated in FIG. 5, the level shifter 23A includes a transmission circuit 23A1 modulating the signal in the first semiconductor chip 29A, a pulse transformer 23A2 as a coupled circuit transmitting the modulated signal by a magnetic coupling form, and a receiving circuit 23A3 demodulating the transmitted signal in the second semiconductor chip 29B. In the similar manner, the level shifter 23B includes a transmission circuit 23B1, a pulse transformer 23B2 as a coupled circuit, and a receiving circuit 23B3, and the level shifter 23C includes a transmission circuit 23C1, a pulse transformer 23C2 as a coupled circuit, and a receiving circuit 23C3.

According to the present embodiment 2 described above, the plurality of parallel signals can be transmitted from the first semiconductor chip 29A to the second semiconductor chip 29B at a high speed. Since the first semiconductor chip 29A to which the MCU 1 is provided and the second semiconductor chip 29B to which the power semiconductor elements 31A to 31C are provided are insulated from each other, electrical safety can be ensured.

Although the coupled circuit includes the pulse transformer transmitting the signal by the magnetic coupling form in the above description, the configuration is not limited thereto. For example, the coupled circuit may include a capacitor transmitting a signal by a capacitance coupling form in place of the pulse transformer. According to such a configuration, easy increase of insulating resistance and suppression of influence of magnetism can be expected. For example, the coupled circuit may include a photocoupler transmitting a signal by an optical coupling form in place of the pulse transformer. According to such a configuration, suppression of cost by an inexpensive photocoupler and facilitation of manufacture using insulation properties of the package 28 can be expected.

In the present disclosure in English, “a” and “an” indicates one or more matters. Thus, “a”, “an”, “one or more”, and “at least one”can be used in the same sense.

Each embodiment and each modification example can be arbitrarily combined, or each embodiment and each modification can be appropriately varied or omitted.

The aspects of the present disclosure are collectively described hereinafter as appendixes.

### Appendix 1

A power semiconductor drive device, comprising:
a conversion circuit converting a serial signal from an outer part into a plurality of parallel signals;
a plurality of drive circuits driving a plurality of power semiconductor elements each having reference potential different from each other, respectively;
a plurality of level shift circuits connected between the conversion circuit and the plurality of drive circuits and level-shifting the plurality of parallel signals in accordance with the reference potential of the plurality of power semiconductor elements, respectively; and
a voltage holding structure electrically separating each of the plurality of drive circuits.

### Appendix 2

The power semiconductor drive device according to Appendix 1, wherein
the conversion circuit, the plurality of drive circuits, the plurality of level shift circuits, and the voltage holding structure are provided on one semiconductor substrate.

### Appendix 3

The power semiconductor drive device according to Appendix 1 or 2, wherein
the voltage holding structure includes a high-voltage RESURF structure using pn junction.

### Appendix 4

The power semiconductor drive device according to Appendix 1 or 2, wherein
the voltage holding structure includes a structure using dielectric isolation.

### Appendix 5

The power semiconductor drive device according to any one of Appendixes 1 to 4, wherein
the conversion circuit is provided to a first semiconductor chip,
the plurality of drive circuits and the voltage holding structure are provided to a second semiconductor chip insulated from the first semiconductor chip, and
each of the plurality of level shift circuits includes a coupled circuit transmitting a signal from the first semiconductor chip to the second semiconductor chip while keeping insulation between the first semiconductor chip and the second semiconductor chip.

### Appendix 6

The power semiconductor drive device according to Appendix 5, wherein
the coupled circuit includes a pulse transformer transmitting the signal by a magnetic coupling form.

### Appendix 7

The power semiconductor drive device according to Appendix 5, wherein
the coupled circuit includes a capacitor transmitting the signal by a capacitance coupling form.

### Appendix 8

The power semiconductor drive device according to Appendix 5, wherein
the coupled circuit includes a photocoupler transmitting the signal by an optical coupling form.

While the disclosure has been shown and described in detail, the foregoing description is in all aspects illustrative and not restrictive. It is therefore understood that numerous modifications and variations can be devised.

What is claimed is:

1. A power semiconductor drive device, comprising:
a conversion circuit converting a serial signal from an outer part into a plurality of parallel signals;
a plurality of drive circuits driving a plurality of power semiconductor elements each having reference potential different from each other, respectively;
a plurality of level shift circuits connected between the conversion circuit and the plurality of drive circuits and level-shifting the plurality of parallel signals in accordance with the reference potential of the plurality of power semiconductor elements, respectively; and
a voltage holding structure electrically separating each of the plurality of drive circuits.

2. The power semiconductor drive device according to claim 1, wherein
the conversion circuit, the plurality of drive circuits, the plurality of level shift circuits, and the voltage holding structure are provided on one semiconductor substrate.

3. The power semiconductor drive device according to claim 1, wherein
the voltage holding structure includes a high-voltage RESURF structure using pn junction.

4. The power semiconductor drive device according to claim 1, wherein
the voltage holding structure includes a structure using dielectric isolation.

5. The power semiconductor drive device according to claim 1, wherein
the conversion circuit is provided to a first semiconductor chip,
the plurality of drive circuits and the voltage holding structure are provided to a second semiconductor chip insulated from the first semiconductor chip, and
each of the plurality of level shift circuits includes a coupled circuit transmitting a signal from the first semiconductor chip to the second semiconductor chip while keeping insulation between the first semiconductor chip and the second semiconductor chip.

6. The power semiconductor drive device according to claim 5, wherein
the coupled circuit includes a pulse transformer transmitting the signal by a magnetic coupling form.

7. The power semiconductor drive device according to claim 5, wherein
the coupled circuit includes a capacitor transmitting the signal by a capacitance coupling form.

8. The power semiconductor drive device according to claim 5, wherein
the coupled circuit includes a photocoupler transmitting the signal by an optical coupling form.
